(19) United States
(12) Patent Application Publication
(10) Pub. No.: US 2006/0284642 A1
(43) Pub. Date: Dec. 21, 2006

(54) Method of inspecting array substrate and method of manufacturing array substrate

(76) Inventor: Satoru Tomita, Kawagoe-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/508,858

(22) Filed: Aug. 24, 2006

Related U.S. Application Data
(63) Continuation of application No. PCT/JP05/02814, filed on Feb. 22, 2005.

(30) Foreign Application Priority Data
Feb. 27, 2004 (JP) 2004-054894

(51) Int. Cl. G01R 31/26

(52) U.S. Cl. 324/765

(57) ABSTRACT

A method of inspecting an array substrate which comprises a substrate, a plurality of scanning lines formed on the substrate and extending in a row direction, a plurality of signal lines extending in a columnar direction to intersect the scanning lines, and a plurality of pixel portions formed on the substrate and including switching elements of thin film transistors formed in the vicinity of intersections of the scanning lines and signal lines, auxiliary capacitors and pixel electrodes, the method comprising: inspecting existence of a defect of the array substrate before providing the pixel electrodes on the pixel portions; and inspecting existence of a defect of the array substrate after providing the pixel electrodes on the pixel portions.

### CROSS-REFERENCE TO RELATED APPLICATIONS

This is a Continuation Application of PCT Application No. PCT/JP2005/002814, filed Feb. 22, 2005, which was published under PCT Article 21(2) in Japanese.

This application is based upon and claims the benefit of priority from prior Japanese Patent Application No. 2004-054894, filed Feb. 27, 2004, the entire contents of which are incorporated herein by reference.

### BACKGROUND OF THE INVENTION

1. Field of the Invention

The present invention relates to a method of inspecting an array substrate which is, for example, a component of a liquid crystal display panel and a method of manufacturing an array substrate.

2. Description of the Related Art

A liquid crystal display panel is used for various parts such as a display unit of a notebook-size personal computer (notebook PC), a display unit of a cellular telephone, a display unit of a television receiver and the like. The liquid crystal display panel comprises an array substrate on which a plurality of pixel electrodes are arranged in matrix, an opposite substrate having opposite electrode which are provided opposite to the plural pixel electrodes, and a liquid crystal layer held between the array substrate and the opposite substrate.

The array substrate comprises a plurality of pixel electrodes arranged in matrix, a plurality of scanning lines arranged along rows of the plural pixel electrodes, a plurality of signal lines arranged along columns of the plural pixel electrodes, and a plurality of switching elements arranged in the vicinity of intersections of the scanning lines and signal lines.

There are two types of array substrates, i.e. an array substrate in which the switching elements are thin film transistors using amorphous silicon semiconductor thin films, and an array substrate in which the switching elements are polysilicon semiconductor thin films. Polysilicon has higher carrier mobility than amorphous silicon. As for the polysilicon type array substrate, not only switching elements for pixel electrodes, but driving circuits of the scanning lines and signal lines can be incorporated into the array substrate.

The array substrate is made to pass through an inspection step, to detect a defective product during its manufacturing process. Some techniques for inspection methods and inspecting apparatuses are disclosed in Jpn. Pat. Appln. KOKAI Publication No. 11-271177, Jpn. Pat. Appln. KOKAI Publication No. 2000-3142 and U.S. Pat. No. 5,268,638.

Jpn. Pat. Appln. KOKAI Publication No. 11-271177 discloses a technique of a characteristic point defect inspection process for inspection of an amorphous type LCD substrate. This technique uses a fact that by applying a direct light beam of a DC component to an entire surface of a LCD substrate, the amorphous silicon film which is light-sensitive becomes conductive. The defect conditions can be determined by detecting the leak of charges stored in an auxiliary capacity. The technique disclosed in Jpn. Pat. Appln. KOKAI Publication No. 2000-3142 uses a fact that when an electron beam is applied to the pixel electrodes, emitted secondary electrons are proportional to the voltage applied to the thin film transistors. Even the technique disclosed in U.S. Pat. No. 5,268,638 uses secondary electrons emitted when the electron beam is applied to the pixel electrodes.

Incidentally, the product price of the liquid crystal display panel is greatly influenced by the yield of the product. The yield is also influenced by whether or not a defect is found in the product during the manufacturing process and the repair rate is high.

### BRIEF SUMMARY OF THE INVENTION

The present invention aims to provide an array substrate inspection method and an array substrate manufacturing method, which, if a defect is found during the manufacturing process of the liquid crystal display panel, can improve the yield of the product by raising the rate of detecting the defect and raising the repair rate therefor and can thereby lower the product price.

According to an aspect of the present invention, there is provided a method of inspecting an array substrate which comprises a substrate, a plurality of scanning lines formed on the substrate and extending in a row direction, a plurality of signal lines extending in a columnar direction to intersect the scanning lines, and a plurality of pixel portions formed on the substrate and including switching elements of thin film transistors formed in the vicinity of intersections of the scanning lines and signal lines, auxiliary capacitors and pixel electrodes, the method comprising:

inspecting existence of a defect of the array substrate before providing the pixel electrodes on the pixel portions; and

inspecting existence of a defect of the array substrate after providing the pixel electrodes on the pixel portions.

According to another aspect of the present invention, there is provided a method of manufacturing an array substrate, comprising:

forming wirings, switching elements connected to the wirings, first pads and second pads configured to receive electric signals from outside;

electrically inspecting the wirings by supplying the electric signals from the first pads to the wirings in a state that the first pads are electrically connected to the wirings;

forming pixel electrodes to be connected to the switching elements; and

supplying the electric signals from the second pads to the pixel electrodes via the first pads and the wirings in a state that the second pads are electrically connected to the first pads, applying electron beams to the pixel electrodes, and thereby inspecting existence of defects in the pixel electrodes in accordance with information of secondary electrons emitted from the pixel electrodes.

According to still another aspect of the present invention, there is provided a method of manufacturing an array substrate having an array substrate main area and an array substrate sub-area, the array substrate which comprises a substrate, a plurality of scanning lines formed on the substrate and extending in a row direction, a plurality of signal lines extending in a columnar direction to intersect the scanning lines, a plurality of pixel portions formed on the substrate and including switching elements of thin film transistors using polysilicon formed in the vicinity of intersections of the scanning lines and signal lines, auxiliary capacitors and pixel electrodes, a scanning line driving circuit provided on the substrate and connected to the plurality of scanning lines to supply scanning line driving signals in the columnar direction to the plurality of pixel portions, and a signal line driving circuit provided on the substrate and connected to the plurality of signal lines to supply signal line driving signals in the row direction to the plurality of pixel portions, the method comprising:

forming a plurality of normal pads to be connected to the scanning line driving circuit and signal line driving circuit, in the array substrate main area;

forming a plurality of common pads in the array substrate sub-area, grouping by the kind a plurality of logic terminals, a plurality of power supply terminals and a plurality of signal input terminals, of a plurality of terminals in the scanning line driving circuit and signal line driving circuit, as a plurality of terminal groups, and connecting the plurality of terminals in each of the terminal groups to any one of the plurality of common pads formed on the substrate, and setting the plurality of common pads and normal pads in an non-connected state;

inspecting the array substrate, in the non-connected state, before providing the pixel electrodes on the plurality of pixel portions;

connecting the common pads and the normal pads after inspection executed before providing the pixel electrodes; and

inspecting existence of defects in the array substrate after connecting the common pads and the normal pads.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram showing a basic structure of an amorphous silicon type array substrate, to explain a technique on which the present invention is based;

FIG. 2 is a diagram showing a basic structure of a polysilicon type array substrate, to explain a technique on which the present invention is based;

FIG. 3 is a schematically cross-sectional view showing a liquid crystal display panel according to an embodiment of the present invention;

FIG. 4 is a perspective view showing a part of the liquid crystal display panel;

FIG. 5 is an illustration showing an alignment example of array substrates on a mother substrate;

FIG. 6 is a schematic view showing an array substrate according to the embodiment of the present invention;

FIG. 7 is a partly enlarged schematic plan view showing a pixel area of the array substrate shown in FIG. 6;

FIG. 8 is a schematic cross-sectional view showing a liquid crystal display panel comprising the array substrate shown in FIG. 7;

FIG. 9 is a flowchart showing an inspection method according to the embodiment of the present invention;

FIG. 10 is an illustration showing main portions of the array substrate on which a color filter and pixel electrodes are to be formed, according to the embodiment of the present invention;

FIG. 11 is an illustration showing main portions of the array substrate on which the color filter and pixel electrodes have been formed, according to the embodiment of the present invention; and

FIG. 12 is an illustration showing a basic structure and operations of an electron beam tester according to the embodiment of the present invention.

### DETAILED DESCRIPTION OF THE INVENTION

An array substrate inspection method and an array substrate manufacturing method according to the embodiment of the present invention, will be described below with reference to the accompanying drawings.

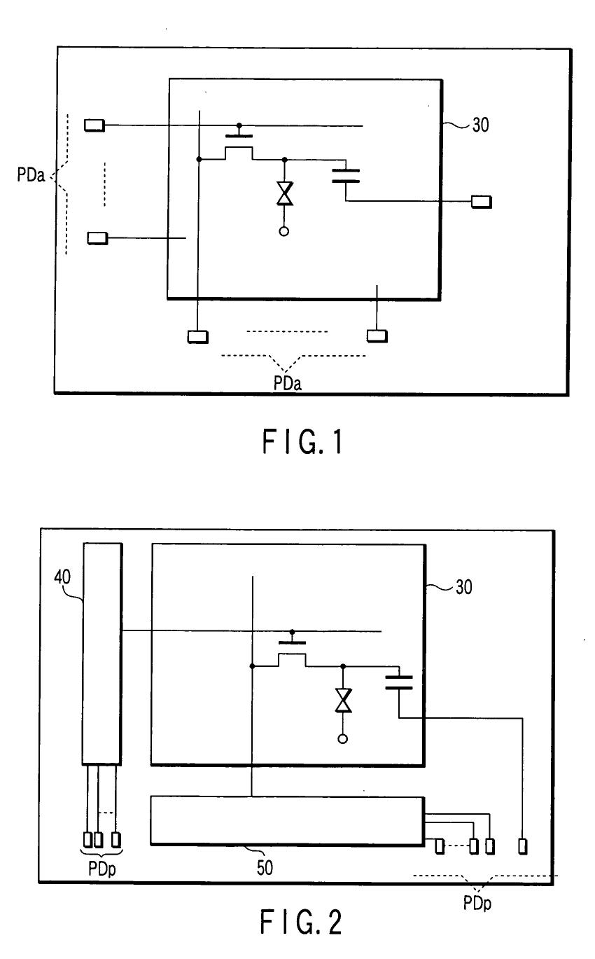

First, a technique on which the present invention is based will be explained. There are two types of array substrates, i.e. an amorphous silicon type array substrate and a polysilicon type array substrate as shown in FIG. 1 and FIG. 2. XGA (extended Graphics Array) is explained as an example. An amorphous silicon type array substrate has a pixel area 30 and a pad group PDa consisting of about three thousand terminals for external circuit connection. On the other hand, on a polysilicon type array substrate, a scanning line driving circuit 40 and a signal line driving circuit 50, for driving pixels of all of X and Y coordinates are formed besides the pixel area 30. These circuits are formed of thin film transistors (hereinafter referred to as TFT). Thus, the total number of terminals of pad group PDp is about three hundred since the terminals are necessary only for inputs of the scanning line driving circuit 40 and signal line driving circuit 50.

Product inspection is required for the array substrate, during its manufacturing process. To inspect conditions of the pixel area 30, an electric tester and an electron beam tester (hereinafter called EB tester) are used. The inspection using the electric tester is executed by storing electric charges in auxiliary capacities of the pixel portions and reading the stored electric charges with a probe. The inspection using the EB tester is executed by storing electric charges in auxiliary capacities of the pixel portions, applying an electron beam to the pixel portions and detecting secondary electrons emitted therefrom.

If the amorphous silicon type array substrate is inspected by using the electric tester, about three thousand testers are necessary for the inspection. In this case, high costs are required for the probes since the probes are very expensive. If the polysilicon type array substrate is inspected by using the electric tester, about three hundred testers are necessary for the inspection. Although the number of probes are reduced, the inspection cannot be preferably executed since it is executed via the scanning line driving circuit 40 and signal line driving circuit 50. In addition, signal processing for the inspection is complicated.

On the other hand, if the amorphous silicon type array substrate is inspected by using the EB tester, electric charges from a common probe are stored in the auxiliary capacities of the pixel portions via the plural terminals of the pad group PDp and then the inspection using the EB tester is executed. If the polysilicon type array substrate is inspected by using the EB tester, electric charges can be stored in the auxiliary capacities of the pixel portions. However, since the pad group PDp has various terminals for different input signals, the auxiliary capacity cannot be charged by a common probe, unlike the amorphous silicon type array substrate.

As described above, four manners of inspecting the amorphous silicon type array substrate and the polysilicon type array substrate by using the electric tester and the EB tester have been explained. Next, a method and an apparatus for inspecting the polysilicon type array substrate by using the EB tester will be explained.

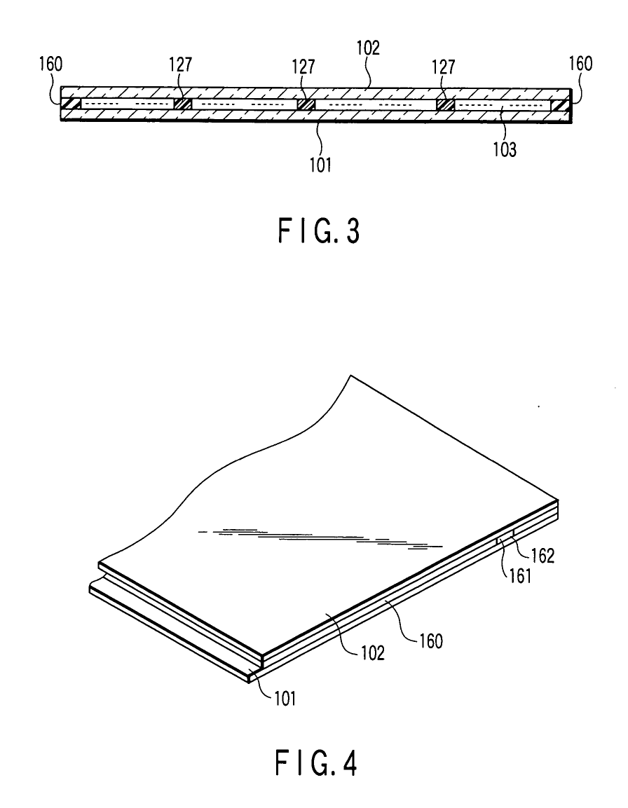

The liquid crystal display panel having the polysilicon type array substrate will be explained with reference to FIG. 3 and FIG. 4. The polysilicon type array substrate will be explained below as array substrate 101. The liquid crystal display panel comprises the array substrate 101, an opposite substrate 102 arranged opposite to the array substrate by retaining a predetermined gap from the array substrate, and a liquid crystal layer 103 sandwiched between the substrates, as shown in FIG. 3 and FIG. 4. The array substrate 101 and the opposite substrate 102 retain a predetermined gap by columnar spacers 127 serving as spacers. Peripheral portions of the array substrate 101 and opposite substrate 102 are bonded to each other by a sealing member 160. A liquid crystal inlet 161 formed at a part of the sealing member 160 is sealed by a sealant 162.

The array substrate 101 is described in detail with reference to FIG. 5. FIG. 5 shows a substrate 100 (hereinafter called mother substrate) having greater dimensions than the array substrate, illustrating an example that four array substrates 101 are formed by using the mother substrate. Thus, when array substrates 101 are formed, the mother substrate 100 is generally used. A structure of one array substrate 101 will be explained below. The array substrate 101 has a main area and a sub-area as specific features of the present invention. They will be described later.

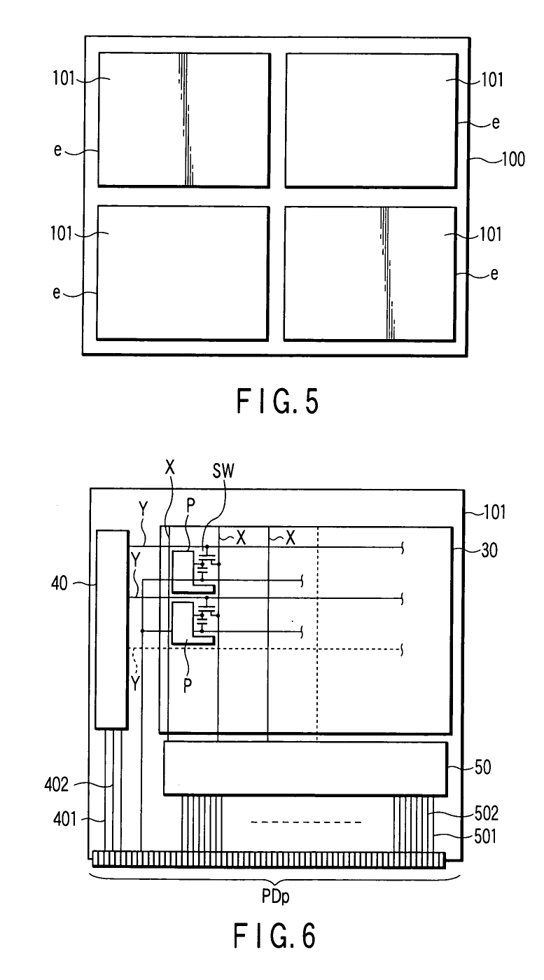

As shown in FIG. 6, a plurality of pixel electrodes P are arranged in matrix, in the pixel area 30 of the array substrate 101. Besides the pixel electrodes P, the array substrate 101 comprises a plurality of scanning lines Y arranged along rows of the pixel electrodes P and a plurality of signal lines X arranged along columns of the pixel electrodes P. The array substrate 101 further comprises TFTs SW arranged in the vicinity of intersections of the scanning lines Y and signal lines X as switching elements, the scanning line driving circuit 40 which drives the plural scanning lines, and the signal line driving circuit 50 which drives the plural signal lines.

Each TFT SW applies a signal voltage of a corresponding signal line X when the TFT is driven via corresponding scanning line Y. The scanning line driving circuit 40 and the signal line driving circuit 50 are arranged adjacent to end portions of the array substrate 101, outside the pixel area 30. The scanning line driving circuit 40 and the signal line driving circuit 50 are formed with TFTs using polysilicon semiconductor films, similarly to the TFTs SW.

The array substrate 101 further comprises a pad group PDp consisting of a plurality of terminals aligned along a cutaway line side of the array substrate and connected to the scanning line driving circuit 40 and the signal line driving circuit 50. The pad group PDp is used to input different signals, and input and output inspection signals. The array substrates 101 are separated from each other by, for example, cutting the mother substrate 100 along edges e (FIG. 5) of the array substrates.

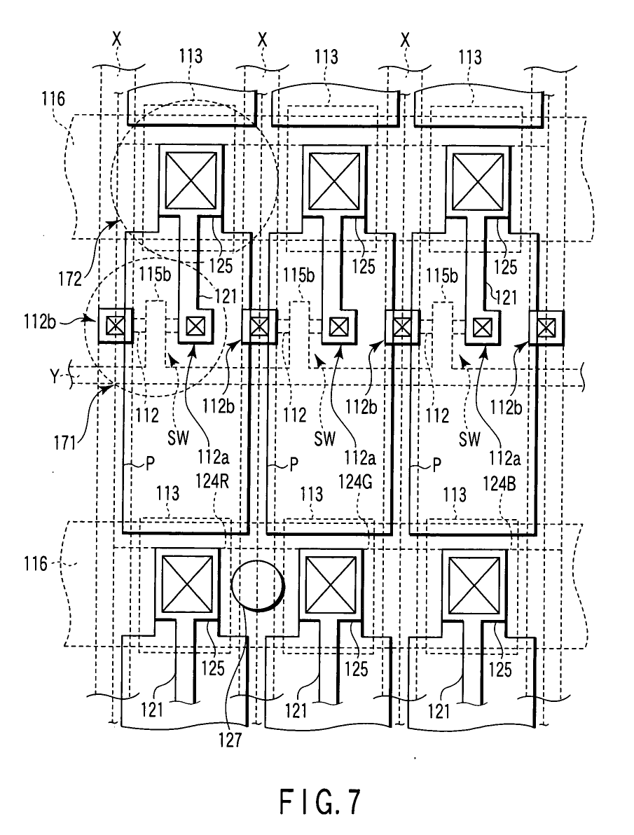

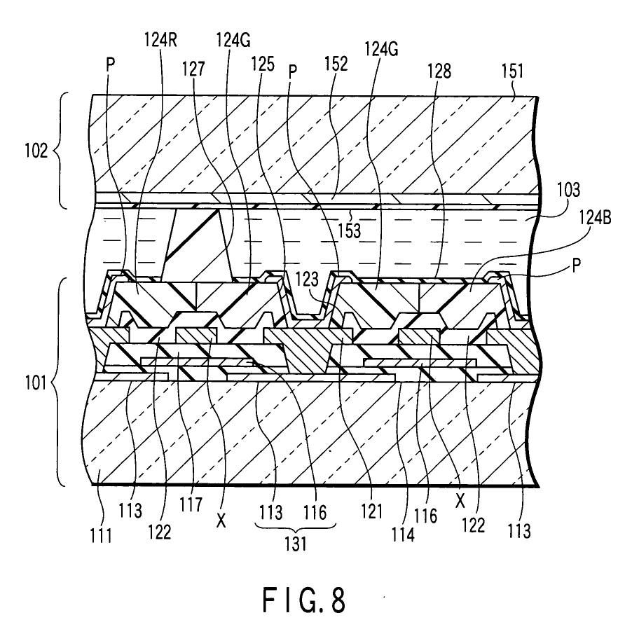

The part of the pixel area 30 shown in FIG. 6 is further explained with reference to FIG. 7 and FIG. 8. FIG. 7 is a plan view and FIG. 8 is a cross-sectional view. The array substrate 101 has substrate 111 as a transparent insulated substrate (glass) (FIG. 8). In the pixel area 30, on the substrate 111, a plurality of signal lines X and a plurality of scanning lines Y are arranged in matrix and the TFTs SW are provided at each of the intersections of the signal lines and scanning lines (see a part surrounded by circle 171 of FIG. 7).

The TFT SW has a semiconductor film 112 which is formed of polysilicon and includes source/drain areas 112a, 112b, and a gate electrode 115b formed by extending a part of the scanning line Y.

On the substrate 111, a plurality of stripe-shaped auxiliary capacity lines 116 are formed to form auxiliary capacity elements 131 and are extended parallel to the scanning line Y. A corresponding pixel electrode P is formed in this section (see a part surrounded by circle 172 of FIG. 7 and FIG. 8).

For details, the semiconductor films 112 and auxiliary capacity lower electrodes 113 are formed on the substrate 111 and gate insulation film 114 is formed on the substrate including the semiconductor films 112 and the auxiliary capacity lower electrodes 113. The auxiliary capacity lower electrodes 113 are formed of polysilicon, similarly to the semiconductor films 112. The scanning lines Y, the gate electrodes 115b, and auxiliary capacity lines 116 are arranged on the gate insulation film 114. The auxiliary capacity lines 116 and the auxiliary capacity lower electrodes 113 are arranged opposite to each other via the gate insulation film 114. Interlayer insulation film 117 is formed on the gate insulation films 114 including the scanning lines Y, the gate electrodes 115b, and the auxiliary capacity lines 116.

Contact electrodes 121 and the signal lines X are formed on the interlayer insulation film 117. The contact electrodes 121 are connected to the source/drain areas 112a of the semiconductor films 112 and the pixel electrodes P, respectively, via contact holes. The signal lines X are connected to the source/drain areas 112b of the semiconductor films 112 via contact holes.

Protective insulation film 122 is formed to overlap the contact electrodes 121, the signal lines X and the interlayer insulation film 117. Furthermore, stripe-shaped green-colored layers 124G, red-colored layers 124R and blue-colored layers 124B are aligned adjacent and alternately on the protective insulation film 122 to form a color filter.

The pixel electrodes P of transparent conductive films of ITO (indium tin oxide) are formed on the colored layers 124G, 124R and 124B, respectively. The pixel electrodes P are connected to the contact electrodes 121, respectively, via contact holes 125 formed on the colored layers and protective insulation film 122. Peripheral portions of the pixel electrodes P are positioned to overlap the auxiliary capacity lines 116 and the signal lines X. Auxiliary capacity elements 131 connected to the pixel electrodes P function as auxiliary capacities to store electric charges.

A columnar spacer 127 (FIG. 7) is formed on the colored layers 124R and 124G. A plurality of columnar spacers 127 are formed on the respective colored layers with desired density though not shown. An alignment film 128 is formed on the colored layers 124G, 124R and 124B and the pixel electrodes P. The opposite substrate 102 has a substrate 151 as a transparent insulation substrate. An opposite electrode 152 formed of a transparent material such as ITO and an alignment film 153 are formed in order, on the substrate 151.

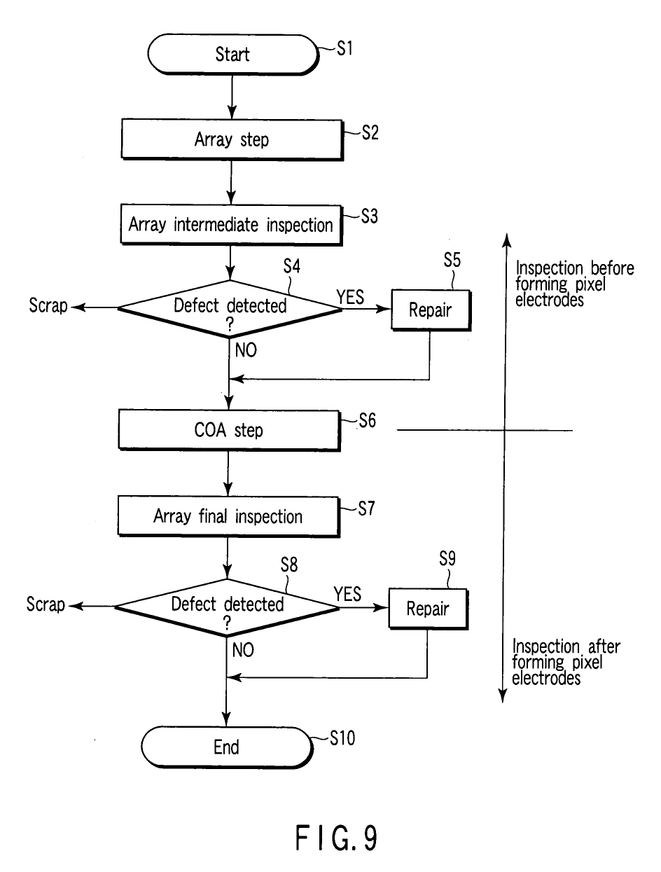

FIG. 9 schematically shows a process of inspecting the array substrate 101 at two stages. When inspection of the array substrate is started in Step S1, an array substrate on which a color filter is to be formed is formed in array step of Step S2. Next, the array substrate is inspected with an electric tester, as an array intermediate inspection of Step S3. If a defect in the array substrate is detected in Step S4, the array substrate is transferred to a repairing step (Step S5) for repairing the array substrate or a scrapping step.

If the array substrate is preferable or has been repaired, the array substrate is transferred to a COA (color filter on array) step (Step S6). In this step, the color filter and the pixel electrodes are formed on the array substrate. Next, the array substrate having the pixel electrodes formed thereon is inspected with an electron beam as an array final inspection, in Step S7. For more details, the electron beam is applied to the pixel electrodes P charged, and secondary electrons emitted from the pixel electrodes P are detected and analyzed. It is thereby inspected whether or not the pixel electrodes normally retain the electric charges. The inspection of this step does not imply only inspection of defectiveness in the pixel electrodes P, but also inspection associated with the pixel electrodes such as defectiveness in TFT SW connected to the pixel electrodes, defectiveness in the auxiliary capacity elements 131 including the pixel electrodes, and the like.

If a defect is detected in the array substrate in Step S8, the array substrate is transferred to a repairing step (Step S9) for repairing the array substrate or a scrapping step. The array midpoint inspection is referred to as first step and the array final inspection is referred to as second step. If the array substrate is preferable or has been repaired, the inspection of the array substrate is ended (Step S10).

An advantage of executing the first step before the second step in the above-described inspection process is explained. It is assumed here that a defective array substrate is detected when the array substrates are inspected in the second step alone. For example, if the defect is caused by a break in the array wiring such as signal lines, scanning lines and the like. Since the second step is executed after formation of the color filter and pixel electrodes, the array wiring of the lower layer cannot be repaired. By executing the first step, however, repairing can be executed even if the array wiring is broken. Thus, the array substrates to be transferred to the scraping step can be reduced in the second step. In addition, the yield of the products can be improved by detecting and repairing the defective array substrate as soon as possible and, consequently, the manufacturing costs can be reduced.

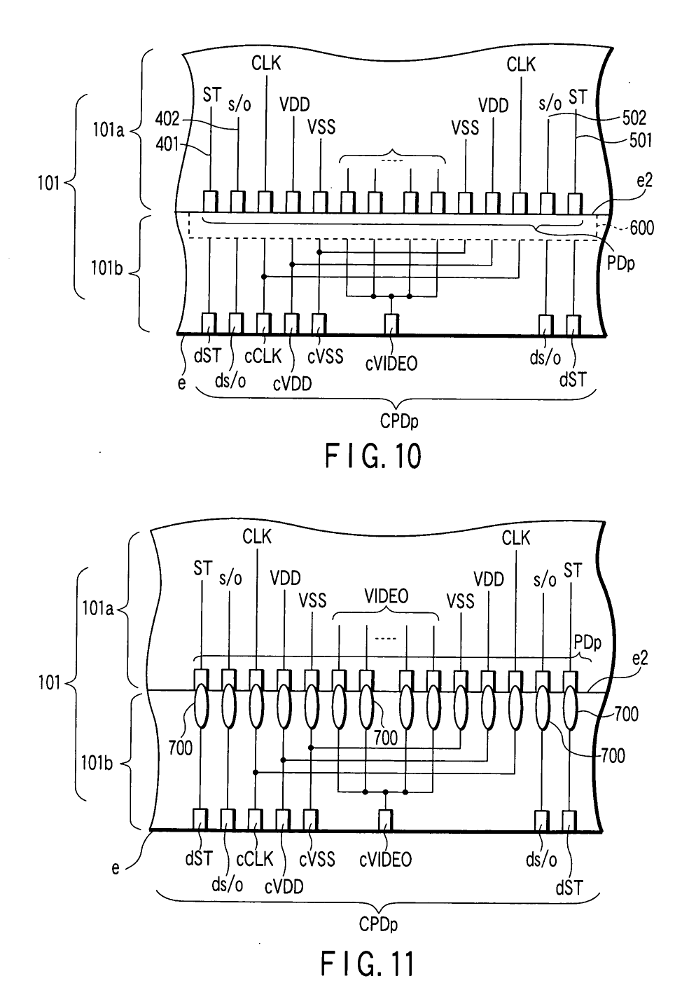

FIG. 10 is a partly enlarged illustration of the array substrate inspected in the first step, showing an example of the pad group PDp provided on the part of the array substrate. The array substrate 101 has an array substrate main area 101a, and an array substrate sub-area 101b provided outside the array substrate main area 101a. The array substrate sub-area 101b is cut out by drawing, for example, a scribe line along cutaway line e2 after the second step is ended.

A connection pad group CPDp is provided on an edge of the array substrate sub-area 101b. The connection pad group CPDp is formed to be connected to the pad group PDp on the array substrate main area 101a side via the wiring. At a non-connecting portion 600 of the array substrate on which the color filter is to be formed, the connection pad group CPDp and the pad group PDp are formed to be in non-connected state. This point, i.e. the relationship of connection between the connection pad group CPDp and the pad group PDp is an essential feature of the present invention.

The pad group PDp of the array substrate main area 101a will be explained. The pad group PDp includes a plurality of normal terminals. The plural normal terminals are connected to the scanning line driving circuit 40 and the signal line driving circuit 50 shown in FIG. 6, respectively, via the wiring. The terminals included in the pad group PDp arranged in this area are classified into logic terminals, power supply terminals, inspection terminals and signal input terminals.

The logic terminals include terminals CLK and terminals ST. Signals to be input to the terminals CLK and terminals ST are a clock signal and a start pulse signal. The clock signal and the start pulse signal are input to the scanning line driving circuit 40 and the signal line driving circuit 50, respectively. For this reason, the pad group PDp includes, for example, two terminals ST. In addition, since the clock signal is input at, for example, two portions, two terminals CLK are provided.

The inspection terminals are serial OUT terminals s/o. Two or more serial OUT terminals s/o are provided, similarly to the clock terminals CLK and start pulse terminals ST. Signals output from the terminals s/o are serial outputs which are output from shift registers (s/r) of the scanning line driving circuit 40 and the signal line driving circuit 50 that respond to start pulse signal.

The power supply terminals include plural kinds of terminals such as terminals VDD, terminals VSS, and the like. In other words, the power supply terminals are classified into two kinds, terminals VDD and terminals VSS. Signals input to the terminals VDD and terminals VSS are a high-level power supply and a low-level power supply. Two terminals VDD and two terminals VSS are provided, similarly to the terminals CLK. Signal input terminals are terminals VIDEO. A signal input to the terminals VIDEO is, for example, a video signal. Hundreds of terminals VIDEO are provided, which accounts for a large share of the pad group PDp.

The connection pad group CPDp of the array substrate sub-area 101b will be explained. The pad group PDp is classified into the terminals to which the same signal is input and is regarded as a plurality of terminal groups. The common connection pad group CPDp is prepared for the classified terminal groups. Common terminals are clock common terminals cCLK, high-level common terminals cVDD, low-level common terminals cVSS, and signal common terminals cVIDEO. The common terminals are aligned along edge e of the array substrate sub-area 101b. The common terminals are aligned to be in a non-connected state with the pad group PDp of the corresponding array substrate main area 101a.

When the above-constituted array substrate on which the color filter is to be formed is inspected with the electric tester, the probe is connected to each of the pads PDp of the array substrate 101, the scanning line driving signal and the signal line driving signal are supplied to the pixel portions via the scanning line driving circuit 40 and the signal line driving circuit 50, and electric charges are stored in the auxiliary capacities of the pixel portions. After that, existence of defects in each of the pixel portions is detected by reading the stored electric charges via the probe.

In addition, when the pixel portions are inspected, existence of defects in the scanning line driving circuit 40 and the signal line driving circuit 50 of the array substrate 101 can also be detected simultaneously. As shown in FIG. 6 and FIG. 10, traces 401 and 402 connected to the scanning line driving circuit 40 are connected to the terminal ST and the terminal s/o, respectively. Similarly, traces 501 and 502 connected to the signal line driving circuit 50 are connected to the other terminal ST and the other terminal s/o, respectively.

The scanning line driving circuit 40 and the signal line driving circuit 50 have shift registers (s/r). For this reason, when the start pulse is input from the terminals ST to the scanning line driving circuit 40 and the signal line driving circuit 50, they output serial outputs via the shift registers. As described above, the terminals ST and the terminals s/o are connected to common terminals dST and the common terminals ds/o, respectively.

Thus, when the array substrate 101 is inspected with the electric tester, the scanning line driving circuit 40 and the signal line driving circuit 50 can also be inspected simultaneously by applying the voltage to the terminals ST and terminals s/o of the pad group PDp, too, via the probe. Defects in the scanning line driving circuit 40 and the signal line driving circuit 50 can be thereby found.

By setting the connection pad group CPDp and the pad group PDp in the non-connected state as described above, inspection using the electric tester can be executed.

Next, the second step will be explained. FIG. 11 is a partly enlarged illustration of the array substrate on which the color filter and pixel electrodes have been formed, showing an example of the pad group PDp provided on the part of the array substrate. The pad group PDp and the connection pad group CPDp of the array substrate 101 on which the pixel electrodes have been formed are set in a connected state via connecting portions 700. When the connecting portions 700 are formed as described above, ITO is used as the same material, for example, similarly to the pixel electrodes. Comprising this step is also a characteristic feature of the present invention.

The relationship of connection between the above-described pad group PDp and connection pad group CPDp will be explained. The terminals ST and the terminals s/o of the array substrate main area 101a are connected to dependent terminals dST and dependent terminals ds/o of the array substrate sub-area 101b, respectively, via the wiring. This is because the terminals ST and the terminals s/o do not belong to the same classification.

The plural terminals CLK of the array substrate main area 101a side are in the same classification and are therefore commonly connected to terminals cCLK. The plural terminals VDD of the array substrate main area 101a side are in the same classification and are therefore connected to common terminals cVDD. The plural terminals VSS of the array substrate main area 101a side are in the same classification and are therefore connected to common terminals cVSS. The plural terminals VIDEO of the array substrate main area 101a side are in the same classification and are therefore connected to common terminals cVIDEO of the array substrate sub-area 101b side.

The plural terminals VIDEO are connected to the common terminals cVIDEO as one common pad, but may be connected to a small number of common pads. Thus, the number of pads in the connection pad group CPDp provided in the array substrate sub-area 101b can be considerably reduced as compared with the number of pads in the pad group PDp provided in the array substrate main area 101a. The alignment of the terminals in the connection pad group CPDp can be designed in accordance with the alignment of the probes.

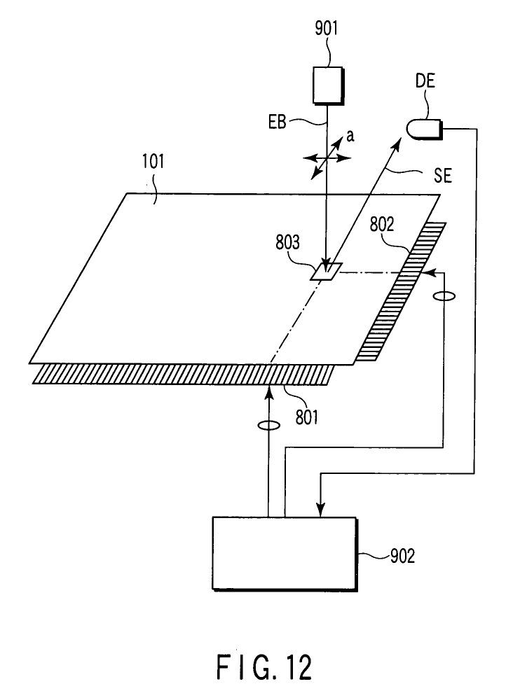

FIG. 12 illustrates a method of inspecting the array substrate 101 by using the EB tester. This inspection is executed after the pixel electrodes P are formed on the substrate and before the array substrates 101 are cut out of the mother substrate 100 along the edge e.

First, a plurality of probes connected to a signal generator and signal analyzer 902 are connected to a plurality of pads 801, 802 (corresponding to the connection pads CPDp shown in FIG. 11). A driving signal output from the signal generator and signal analyzer 902 is supplied to a pixel portion 803 via the probes and the pads 801, 802. After the driving signal is supplied to the pixel portion 803, electron beam EB emitted from an electron source 901 is applied to the pixel portion.

Secondary electrons SE representing the voltage of the pixel portion 803 are emitted by this application. The secondary electrons SE are detected by an electron detector DE. The secondary electrons SE are proportional to the voltage of the portion from which they are emitted. In the inspection step, the pixel portion 803 of the array substrate 101 is electrically scanned by the driving signal from the signal generator and signal analyzer 902. This scanning is executed synchronously with the scanning of the array substrate 101 surface by the electron beam EB as represented by arrow a.

Information about the secondary electrons detected by the electron detector DE is supplied to the signal generator and signal analyzer 902 for the purpose of analyzing the pixel portion 803. Voltage variation corresponding to the secondary electrons represents the state of the pixel portion 803. The information of the secondary electrons supplied to the signal generator and signal analyzer 902 reflects responding performance of each pixel portion to the driving signals supplied to the terminals of TFT of each pixel portion 803. Thereby the state of the voltage of the pixel electrodes P in each pixel portion 803 can be inspected. In other words, if the pixel portion 803 has a defect, the defect can be detected by the EB tester.

According to the above-described array substrate inspection method, array substrate inspection apparatus and array substrate manufacturing method, the array substrate on which the color filter is to be formed is inspected with the electric tester while the array substrate on which the pixel electrodes has been formed is inspected with the EB tester. The defect of the product can be found more effectively in the manufacturing process, and the liquid crystal display panel of high yield can be obtained. In addition, since the connection pad group CPDp has a few pads in the second step, the number of probes of the inspection apparatus is also small. For this reason, high yield can be achieved and preferable inspection can be executed by reducing the manufacturing cost and the costs for the inspection apparatus. When the pixel electrodes P are formed, connection of the pads PDp and connection pads CPDp is processed by the connecting portions 700. Thus, the connection can be processed without increasing the manufacturing steps.

Furthermore, when the pixel portions 803 are inspected, the scanning line driving circuit 40 and the signal line driving circuit 50 are inspected simultaneously. The total time required for the inspection can be thereby shortened. In other words, the scanning line driving circuit 40 and the signal line driving circuit 50 do not need to be inspected by setting a different step.

By aligning the terminals of the connection pad group CPDp in accordance with the alignment of the probes, alignment of the connection pad group CPDp can be made forcefully in accordance with the alignment of the probes of the inspection apparatus even if the arrangement of the pad group PDp in the array substrate main area 101a or its pads is changed. Thus, adaptability of the inspection apparatus can be increased by improving a combination form of the inspection apparatus and the array substrate. In addition, opportunities of changing or modifying the design of the inspection apparatus can be reduced and, as a result, rise in the product price of the panel can be restricted.

Even if the design in the circuit configuration of the array substrate main area 101a is changed, the design of the inspection apparatus does not need to be changed or modified by retaining the alignment of the pad group CPDP of the array substrate sub-area 101b in the same pattern.

What is claimed is:

1. A method of inspecting an array substrate which comprises a substrate, a plurality of scanning lines formed on the substrate and extending in a row direction, a plurality of signal lines extending in a columnar direction to intersect the scanning lines, and a plurality of pixel portions formed on the substrate and including switching elements of thin film transistors formed in the vicinity of intersections of the scanning lines and signal lines, auxiliary capacitors and pixel electrodes, the method comprising:
inspecting existence of a defect of the array substrate before providing the pixel electrodes on the pixel portions; and
inspecting existence of a defect of the array substrate after providing the pixel electrodes on the pixel portions.

2. The method according to claim 1, wherein the array substrate further comprises a scanning line driving circuit provided on the substrate and connected to the plurality of scanning lines to supply scanning line driving signals in the columnar direction to the plurality of pixel portions, and a signal line driving circuit provided on the substrate and connected to the plurality of signal lines to supply signal line driving signals in the row direction to the plurality of pixel portions, and
the inspecting executed before providing the pixel electrodes includes inspecting existence of defects in the plurality of pixel portions, scanning line driving circuit and signal line driving circuit.

3. The method according to claim 1, wherein an electric tester is used in the inspecting executed before providing the pixel electrodes while an electron beam tester is used in the inspecting executed after providing the pixel electrodes.

4. The method according to claim 1, further comprising:
forming a color filter on the substrate between the inspecting executed before providing the pixel electrodes and the inspecting executed after providing the pixel electrodes.

5. The method according to claim 1, further comprising
repairing the array substrate between the inspecting executed before providing the pixel electrodes and the inspecting executed after providing the pixel electrodes.

6. The method according to claim 2, wherein the array substrate is formed such that, of a plurality of terminals in the scanning line driving circuit and signal line driving circuit, a plurality of logic terminals, a plurality of power supply terminals and a plurality of signal input terminals are grouped by the kind as a plurality of terminal groups, and
the inspecting executed after providing the pixel electrodes includes connecting the plurality of terminals in each of the terminal groups are connected to any one of a plurality of common pads formed on the substrate, connecting probes to the plurality of common pads, respectively, and inspecting existence of defects in the array substrate via the probes.

7. The method according to claim 2, wherein the switching elements, the scanning line driving circuit and the signal line driving circuit are formed of elements using polysilicon.

8. A method of manufacturing an array substrate, comprising:
forming wirings, switching elements connected to the wirings, first pads and second pads configured to receive electric signals from outside;
electrically inspecting the wirings by supplying the electric signals from the first pads to the wirings in a state that the first pads are electrically connected to the wirings;
forming pixel electrodes to be connected to the switching elements; and
supplying the electric signals from the second pads to the pixel electrodes via the first pads and the wirings in a state that the second pads are electrically connected to the first pads, applying electron beams to the pixel electrodes, and thereby inspecting existence of defects in the pixel electrodes in accordance with information of secondary electrons emitted from the pixel electrodes.

9. A method of manufacturing an array substrate having an array substrate main area and an array substrate sub-area, the array substrate which comprises a substrate, a plurality of scanning lines formed on the substrate and extending in a row direction, a plurality of signal lines extending in a columnar direction to intersect the scanning lines, a plurality of pixel portions formed on the substrate and including switching elements of thin film transistors using polysilicon formed in the vicinity of intersections of the scanning lines and signal lines, auxiliary capacitors and pixel electrodes, a scanning line driving circuit provided on the substrate and connected to the plurality of scanning lines to supply scanning line driving signals in the columnar direction to the plurality of pixel portions, and a signal line driving circuit provided on the substrate and connected to the plurality of signal lines to supply signal line driving signals in the row direction to the plurality of pixel portions, the method comprising:
forming a plurality of normal pads to be connected to the scanning line driving circuit and signal line driving circuit, in the array substrate main area;
forming a plurality of common pads in the array substrate sub-area, grouping by the kind a plurality of logic terminals, a plurality of power supply terminals and a plurality of signal input terminals, of a plurality of terminals in the scanning line driving circuit and signal line driving circuit, as a plurality of terminal groups, and connecting the plurality of terminals in each of the terminal groups to any one of the plurality of common pads formed on the substrate, and setting the plurality of common pads and normal pads in an non-connected state;
inspecting the array substrate, in the non-connected state, before providing the pixel electrodes on the plurality of pixel portions;
connecting the common pads and the normal pads after inspection executed before providing the pixel electrodes; and
inspecting existence of defects in the array substrate after connecting the common pads and the normal pads.

10. The method according to claim 9, wherein the common pads and the normal pads are connected by using a material identical with a material of the pixel electrodes, simultaneously with forming the pixel electrodes.
